(19) United States
(12) Patent Application Publication
(10) Pub. No.: US 2026/0247769 A1
(43) Pub. Date: Aug. 20, 2026

(54) MICRO-LED TRANSFER SYSTEM AND MICRO-LED TRANSFER METHOD USING SAME

(71) Applicant: SAMSUNG ELECTRONICS CO., LTD., Suwon-si (KR)

(72) Inventors: Byungchul KIM, Suwon-si (KR); Seungryong HAN, Suwon-si (KR); Mingyu LEE, Suwon-si (KR)

(73) Assignee: SAMSUNG ELECTRONICS CO., LTD., Suwon-si (KR)

(21) Appl. No.: 19/645,901

(22) Filed: Apr. 13, 2026

Related U.S. Application Data
(63) Continuation of application No. PCT/KR2024/015407, filed on Oct. 11, 2024.

(30) Foreign Application Priority Data
Oct. 13, 2023 (KR) 10-2023-0136939

(51) Int. Cl. H10H 29/02; H10P 34/42

(52) U.S. Cl. CPC H10H 29/02; H10P 34/42

(57) ABSTRACT

A micro-LED transfer system including a first transfer device to transfer a micro-LED to a second substrate, and/or a second transfer device to transfer the micro-LED to the second substrate. The first transfer device includes a first laser light source unit to irradiate, with a laser beam, the first substrate on which the micro-LED is disposed; a mask unit which is disposed between the first substrate and the first laser light source unit, and which selectively opens and closes at least one aperture; and a processor to control the mask unit such that the opening corresponding to the micro-LED transferred to the second substrate is opened and closed. The first transfer device and/or the second transfer device can transfer the micro-LED to the second substrate, which has an irregular shape.

### CROSS-REFERENCE TO RELATED APPLICATIONS

This application is a continuation application, under 35 U.S.C. § 111(a), of an International Application No. PCT/KR2024/015407, filed on Oct. 11, 2024, which is based on and claims from the benefit of Korean Patent Application Number 10-2023-0136939, filed on Oct. 13, 2023, the disclosures of which is incorporated by reference herein in its entirety.

### TECHNICAL FIELD

Various embodiments of the disclosure relate to a micro light emitting diode (LED) transfer system transferring a plurality of micro LEDs formed on a wafer to a printed circuit board of a display panel and a micro LED transfer method using the same.

### BACKGROUND ART

A micro LED is an ultra-small inorganic luminescent material that emits light by itself without a color filter and a backlight. Specifically, the micro LED has a length of one-tenth and an area of one-hundredth of a general light emitting diode (LED) chip, and may refer to an ultra-small LED having a width, a length, and a height of 10 μm to 100 μm.

The micro LED is manufactured in a chip form on a wafer and is disposed on a target substrate to constitute a light emitting module of a display. A process of disposing the micro LED on the target substrate is a process of efficiently transferring the micro LED to a space of the substrate and electrically or physically connecting the micro LED to the substrate, and is a core process in manufacturing a micro LED display module.

Meanwhile, recently, as various types of display devices such as wearable devices are released, a technology capable of efficiently transferring the micro LED onto a target substrate of various types is needed.

### DISCLOSURE OF INVENTION

### solution to Problems

Various embodiments of the disclosure may provide a micro LED transfer system efficiently transferring a micro LED onto a target substrate having an irregular shape using at least one of a first transfer device and a second transfer device, and a micro LED transfer method using the same.

A micro LED transfer system according to embodiments of the disclosure may include at least one of a first transfer device to transfer a micro LED to a second substrate, and a second transfer device to transfer the micro LED to the second substrate. The first transfer device may include a first laser light source unit to irradiate a laser beam onto a first substrate on which the micro LED is disposed, a mask unit disposed between the first substrate and the first laser light source unit and selectively opening and closing at least one aperture, and a processor controlling the mask unit to open and close the at least one aperture corresponding to the micro LED transferred to the second substrate. At least one of the first transfer device or the second transfer device may transfer the micro LED to the second substrate having an irregular shape.

According to an embodiment, the mask unit may include a curved portion having a predetermined curvature. The processor may form an irregular-shaped laser beam by moving and rotating the mask unit.

According to an embodiment, the mask unit may have a quadrant shape including the curved portion. The processor may form a circle-shaped laser beam by moving and rotating the mask unit.

According to an embodiment, the mask unit may include a first mask shaping the laser beam, and a second mask scanning the laser beam onto the first substrate.

According to an embodiment, the first mask may include a shaping aperture having at least one shape among a rectangle, a triangle, a circle, a semicircle, and a quadrant.

According to an embodiment, the processor may form an irregular-shaped laser beam by moving and rotating the first mask.

According to an embodiment, the first transfer device may transfer the micro LED to the second substrate in a multi transfer manner. The second transfer device may transfer the micro LED to the second substrate in a one-by-one transfer manner.

According to an embodiment, the second transfer device may include a second laser light source unit outputting a laser beam, a path changing unit changing a path of the laser beam, and a second processor controlling the path changing unit to change the path of the laser beam toward the micro LED transferred to the second substrate.

According to an embodiment, the first transfer device may transfer the micro LED to a first region of the second substrate. The second transfer device may transfer the micro LED to a second region of the second substrate.

According to an embodiment, the first region may include a non-curved region of the second substrate. The second region may include a curved region of the second substrate.

A micro LED transfer method according to embodiments of the disclosure may include transferring a micro LED to a second substrate using a first transfer device, and transferring the micro LED to the second substrate using a second transfer device. Transferring the micro LED to the second substrate using the first transfer device may include irradiating a laser beam onto a first substrate on which the micro LED is disposed using a first laser light source unit, selectively opening and closing at least one aperture using a mask unit disposed between the first substrate and the first laser light source unit, and controlling the mask unit to open and close the at least one aperture corresponding to the micro LED transferred to the second substrate using a first processor. At least one of the first transfer device or the second transfer device may transfer the micro LED to the second substrate having an irregular shape.

According to an embodiment, the mask unit may include a curved portion having a predetermined curvature. Controlling the mask unit using the first processor may form an irregular-shaped laser beam by moving and rotating the mask unit.

According to an embodiment, the mask unit may have a quadrant shape including the curved portion. Controlling the mask unit using the first processor may form a circle-shaped laser beam by moving and rotating the mask unit.

According to an embodiment, selectively opening and closing at least one aperture using the mask unit may include shaping the laser beam using a first mask, and scanning the laser beam onto the first substrate using a second mask.

According to an embodiment, the first mask may include a shaping aperture having at least one shape among a rectangle, a triangle, a circle, a semicircle, and a quadrant.

According to an embodiment, controlling the mask unit using the first processor may form an irregular-shaped laser beam by moving and rotating the first mask.

According to an embodiment, the first transfer device may transfer the micro LED to the second substrate in a multi transfer manner. The second transfer device may transfer the micro LED to the second substrate in a one-by-one transfer manner.

According to an embodiment, transferring the micro LED to the second substrate using the second transfer device may include outputting a laser beam using a second laser light source unit, changing a path of the laser beam using a path changing unit, and controlling the path changing unit to change the path of the laser beam toward the micro LED transferred to the second substrate using a second processor.

According to an embodiment, transferring the micro LED to the second substrate using the first transfer device may transfer the micro LED to a first region of the second substrate. Transferring the micro LED to the second substrate using the second transfer device may transfer the micro LED to a second region of the second substrate.

According to an embodiment, the first region may include a non-curved region of the second substrate. The second region may include a curved region of the second substrate.

According to various embodiments of the disclosure, the micro LED transfer system of the disclosure and the micro LED transfer method using the same may transfer the micro LED onto a target substrate having an irregular shape by moving and rotating the mask unit including the curved portion.

Further, the micro LED transfer system of the disclosure and the micro LED transfer method using the same may transfer the micro LED onto a target substrate having an irregular shape by shaping the laser beam with the first mask and scanning the laser beam onto the wafer with the second mask.

Further, the micro LED transfer system of the disclosure and the micro LED transfer method using the same may transfer the micro LED onto a target substrate having an irregular shape by transferring the micro LED to the non-curved portion of the target substrate with the first transfer device in a multi transfer manner and transferring the micro LED to the curved portion of the target substrate with the second transfer device in a one-by-one transfer manner.

Accordingly, the micro LED transfer system of the disclosure and the micro LED transfer method using the same may efficiently transfer the micro LED to a target substrate having an irregular shape applicable to a display device having various shapes.

Effects obtainable from the exemplary embodiments of the disclosure are not limited to the above-mentioned effects, and other effects that are not mentioned is clearly derived and understood by those of ordinary skill in the art to which the exemplary embodiments of the disclosure belong from the following description. In other words, unintended effects in practicing embodiments of the disclosure may also be derived by one of ordinary skill in the art from example embodiments of the disclosure.

### BRIEF DESCRIPTION OF DRAWINGS

FIG. 1 illustrates a first transfer device of a micro LED transfer system according to an embodiment.

FIG. 2 illustrates a partial block configuration of the first transfer device according to an embodiment.

FIG. 3 illustrates the mask unit of the first transfer device according to an embodiment.

FIG. 4 illustrates a first substrate used in the first transfer device according to an embodiment.

FIG. 5 illustrates an enlarged view illustrating the first region of the first substrate of FIG. 4.

FIG. 6 illustrates an enlarged view illustrating a portion A and a portion B of the first region of FIG. 5.

FIG. 7 illustrates a second substrate used in the first transfer device according to an embodiment.

FIG. 8 illustrates a micro LED transfer operation sequence of the first transfer device according to an embodiment.

FIG. 9 illustrates a mask unit including a curved portion according to an embodiment.

FIG. 10 illustrates a mask unit moving and rotating under the control of a processor according to an embodiment.

FIG. 11 illustrates a micro LED transfer operation sequence of the first transfer device according to an embodiment.

FIG. 12 illustrates a laser beam sequentially passing through a first mask and a second mask.

FIG. 13 illustrates a micro LED transfer operation sequence of the first transfer device and a second transfer device according to an embodiment.

FIG. 14 illustrates a first region and a second region of the second substrate.

FIG. 15 illustrates a second transfer device of a micro LED transfer system according to an embodiment.

### MODE FOR THE INVENTION

Hereinafter, embodiments of the disclosure are described in detail with reference to the drawings so that those skilled in the art to which the disclosure pertains may easily practice the disclosure. However, the disclosure may be implemented in other various forms and is not limited to the embodiments set forth herein. The same or similar reference denotations may be used to refer to the same or similar elements throughout the specification and the drawings. Further, for clarity and brevity, no description is made of well-known functions and configurations in the drawings and relevant descriptions.

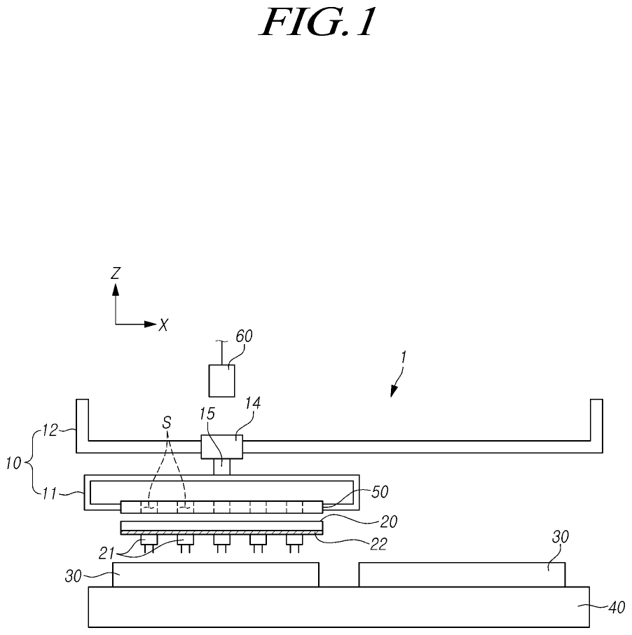

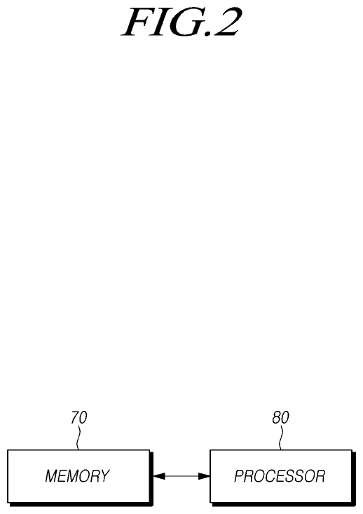

FIG. 1 illustrates a micro LED transfer device according to an embodiment, and FIG. 2 illustrates a partial block configuration of the micro LED transfer device according to an embodiment.

Referring to FIGS. 1 and 2, a first transfer device 1 transferring a micro LED according to an embodiment of the disclosure may include a transfer unit 10 supporting a mask unit 50 to be movable above a first substrate 20, a stage 40 on which a second substrate 30 is seated to be clampable and moving the second substrate 30, a mask unit 50 selectively passing a laser beam radiated onto the first substrate 20, a laser light source unit 60 irradiating a laser beam onto the first substrate 20, and a processor 80 controlling the transfer unit 10, the stage 40, and the mask unit 50, respectively.

According to an embodiment, the transfer unit 10 may include a fixing member 11 supporting the mask unit 50 such that the laser beam is directed toward the second substrate 30, and a guide member 12 to which the fixing member 11 is rotatably connected. Based on the coordinate system illustrated in FIG. 1, the fixing member 11 may be connected to the guide member 12 by a rotation shaft 15 to be movable along the X-axis direction through a slider 14. Further, the fixing member 11 may rotate clockwise or counterclockwise about the rotation shaft 15 disposed along the Z-axis. The guide member 12 may be slidably connected to a guide rail (not illustrated) disposed in the Y-axis direction to move the fixing member 11 in the Y-axis direction.

According to an embodiment, the mask unit 50 may move to an arbitrary position on the XY plane by the fixing member 11 and the guide member 12, and may rotate clockwise and/or counterclockwise about the Z-axis. Although the fixing member 11 is illustrated to fix the mask unit 50 by supporting an edge region of the mask unit 50 as in FIG. 1, the disclosure is not limited thereto, and the mask unit 50 may be stably fixed in various manners. For example, the fixing member 11 may be connected to an arbitrary portion of the mask unit 50 through various clamping structures such as a vacuum suction method to fix the mask unit 50. For convenience of description, illustration of a driving device for rotating the fixing member 11 and a driving device for moving the guide member 12 is omitted in FIG. 1. The guide member 12 is disposed above the second substrate 30 and may move the fixing member 11 connected to the mask unit 50 to an arbitrary position on the XY plane with respect to the second substrate 30. Further, the guide member 12 may move the fixing member 11 through various structures such as a multi-joint structure, a piston structure, and a sliding structure.

According to an embodiment, the first substrate 20 may be a wafer. For example, the first substrate 20 may be a wafer on which a plurality of micro LEDs 21 grown on various substrates such as a sapphire substrate are disposed. An adhesive layer 22 may be located on one surface of the first substrate 20. The adhesive layer 22 may attach the plurality of micro LEDs 21 to the first substrate 20. Further, the adhesive layer 22 may be composed of a material that is melted by a laser beam radiated onto the first substrate 20 such that the micro LED 21 may be separated from the first substrate 20.

According to an embodiment, the micro LED 21 is formed of an inorganic luminescent material having a width, a length, and a height of 100 μm or less, and may emit light by itself in case that power is supplied. The micro LED 21 has a fast response speed, low power, and high luminance, and is attracting attention as a light emitting element of a next-generation display. Specifically, the micro LED 21 may have higher efficiency in converting electricity into photons compared to a liquid crystal display (LCD) or an optical light emitting diode (OLED). Accordingly, the micro LED 21 may emit the same brightness with about half the energy compared to an existing LED or OLED. Further, the micro LED 21 is capable of implementing high resolution, excellent color, contrast, and brightness, and may accurately represent a wide range of colors, and may implement a clear screen even outdoors in bright sunlight. Further, the micro LED 21 is resistant to a burn-in phenomenon, and has low heat generation, so a long lifespan may be ensured without deformation. Further, the micro LED 21 may include at least one of a red micro LED emitting red light, a green micro LED emitting green light, and a blue micro LED emitting blue light. A micro LED emitting light of the same color may be disposed on one wafer. For example, in case that the first substrate 20 is a wafer, the first substrate 20 may be configured only with a red micro LED emitting red light, may be configured only with a green micro LED emitting green light, or may be configured only with a blue micro LED emitting blue light.

According to an embodiment, the micro LED 21 formed on the wafer may include an anode electrode and a plurality of cathode electrodes, respectively. For example, some of the micro LEDs on one wafer may be disposed at 180 degrees (°) with respect to the remaining micro LEDs. Here, the meaning that the remaining micro LEDs are disposed at 180 degrees (°) may be that the anode electrode and the cathode electrode of the remaining micro LEDs are located in an opposite direction with respect to the anode electrode and the cathode electrode of some of the micro LEDs. For example, all micro LEDs on one wafer may be formed such that the anode electrode and the cathode electrode are all in the same direction.

According to an embodiment, the second substrate 30 may be a printed circuit board (PCB) applied to a display panel as a target substrate. The second substrate 30 may be made in various sizes and shapes unlike the first substrate 20. Further, the second substrate 30 may be a relay substrate receiving the micro LED from the first substrate 20 and relaying the micro LED to a printed circuit board of the display panel.

According to an embodiment, the second substrate 30 may be a printed circuit board (PCB) on which the plurality of micro LEDs 21 transferred from the first substrate 20 are mounted. The second substrate 30 may include a plurality of anode electrode pads and a plurality of cathode electrode pads to which each micro LED 21 is physically and/or electrically connected. The plurality of anode electrode pads and the plurality of cathode electrode pads of the second substrate 30 may vary corresponding to an arrangement of an anode electrode and a cathode electrode of the plurality of micro LEDs disposed on the first substrate 20.

For example, in case that the remaining micro LEDs are disposed at 180 degrees (°) with respect to some micro LEDs, the plurality of anode electrode pads and the plurality of cathode electrode pads on the second substrate 30 may be disposed in the same direction. Further, in case that the anode electrode and the cathode electrode of all micro LEDs are all formed in the same direction, some of the plurality of anode electrode pads and the plurality of cathode electrode pads on the second substrate 30 may be disposed at 0 degree (°), and the remaining may be disposed at 180 degrees (°).

According to an embodiment, the stage 40 may support the second substrate 30 to be disposed in parallel with the first substrate 20 while the second substrate 30 is loaded and unloaded, respectively. The stage 40 may move relatively with respect to the transfer unit 10 in a state in which the second substrate 30 is loaded. In other words, the stage 40 may move on the XY plane. Further, the stage 40 may move up and down along the Z-axis direction. For convenience of description, illustration of respective driving devices for XY plane movement and up and down movement of the stage 40 is omitted in FIG. 1.

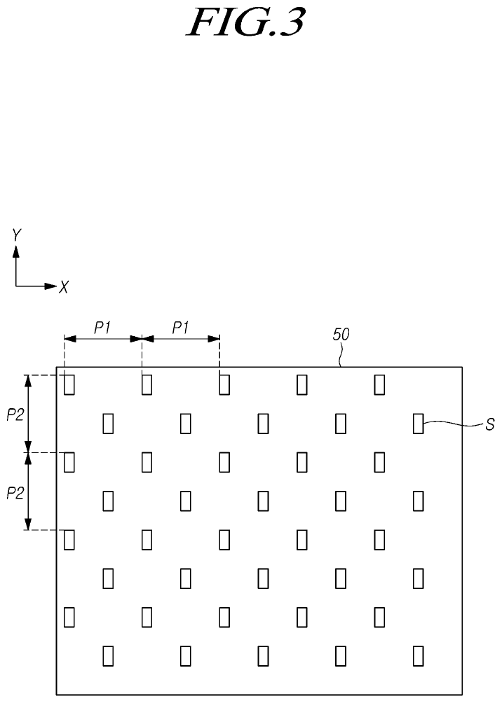

According to an embodiment, the mask unit 50 is disposed between the laser light source unit 60 and the first substrate 20 and may pass a laser beam emitted from the laser light source unit 60 onto the first substrate 20. A specific structure of the mask unit 50 is described below with reference to FIG. 3.

According to an embodiment, the laser light source unit 60 may lift off the plurality of micro LEDs 21 by irradiating a laser beam toward a rear surface of the first substrate 20 on which the plurality of micro LEDs 21 are not formed. The micro LED 21 lifted off from the first substrate 20 by the laser beam may be transferred to the second substrate 30.

According to an embodiment, the laser light source unit 60 may directly radiate a laser beam toward the first substrate 20, or may include a lens member (e.g., P-lens) capable of appropriately changing a direction of the laser beam on a path along which the laser beam is radiated. The laser light source unit 60 may radiate any one of a point laser beam, a line laser beam, and an area laser beam. For example, the point laser beam may be a laser beam radiated toward one point. For example, the line laser beam may be a laser beam radiated with an arbitrary length along the X-axis or the Y-axis. The area beam is a laser beam simultaneously radiated onto an arbitrary region, and a laser beam may be simultaneously or sequentially radiated onto a plurality of [X, Y] coordinate points. In this case, the area laser beam may be simultaneously or sequentially radiated in a plurality of parallel diagonal directions with respect to an arbitrary region.

According to an embodiment, the laser light source unit 60 may be a portion of a laser beam scanner (not illustrated), and the laser beam scanner may be included in the micro LED transfer device according to an embodiment of the disclosure.

A memory 70 illustrated in FIG. 2 may be provided in the first transfer device 1. The memory 70 may be implemented as at least one of a flash memory type, a read only memory (ROM), a random access memory (RAM), a hard disk type, a multimedia card micro type, and a card type memory (e.g., SD or XD memory). Further, the memory 70 is electrically connected to the processor 80 and may transmit a signal and information to/from the processor 80. Accordingly, the memory 70 may store a program programming a series of processes of transferring the plurality of micro LEDs from the first substrate to the second substrate.

According to an embodiment, the processor 80 may be provided in the first transfer device 1, and may control the overall operation of the first transfer device 1. In other words, the processor 80 is electrically connected to the transfer unit 10, the stage 40, the mask unit 50, and the laser light source unit 60, respectively, and may control each of the configurations.

For example, the processor 80 may control the transfer unit 10 to transfer the mask unit 50 to a position on an arbitrary XY plane above the first substrate 20 and rotate the mask unit 50 to a desired angle. Further, the processor 80 may move the stage 40 to a position on an arbitrary XY plane and move the stage 40 in an up and down direction. Further, the processor 80 may control the laser light source unit 60 to scan the laser beam to a preset point toward the first substrate 20.

Although the disclosure describes that all configurations are controlled by one processor 80, the disclosure is not limited thereto, and each configuration may be controlled using a plurality of independent processors.

According to an embodiment, the processor 80 includes a processing circuit and may include, e.g., one or more of a central processing unit (CPU), a controller, an application processor (AP), a communication processor (CP), and an ARM processor. The processor 80 is electrically connected to the memory 70 and may use a program for micro LED transfer stored in the memory 70 and a plurality of pieces of information. Specific functions of the processor 80 according to an embodiment of the disclosure is described below.

FIG. 3 illustrates the mask unit of the first transfer device according to an embodiment.

According to an embodiment, the mask unit 50 may be disposed between the first substrate 20 and the laser light source unit 60 as in FIG. 1. The mask unit 50 may move to an arbitrary position on the XY plane by the fixing member 11 and the guide member 12 of the transfer unit 10, and may rotate clockwise and/or counterclockwise about the Z-axis.

Referring to FIG. 3, according to an embodiment, the mask unit 50 may be formed in a substantially flat plate shape, and a plurality of apertures S may be formed at regular intervals in the X-axis direction and the Y-axis direction so that the laser beam may pass therethrough. The plurality of apertures S formed in the mask unit 50 may have various sizes or shapes through which the laser beam may pass to transfer the micro LED 21 on the first substrate 20 to the second substrate 30.

According to an embodiment, the plurality of apertures S may be disposed at a first pitch P1 in the X-axis direction and may be disposed at a second pitch P2 in the Y-axis direction. In this case, the first pitch P1 and the second pitch P2 may have the same length or different lengths. Here, the first and second pitches P1, P2 may be variously set from several tens of μm to several hundreds of μm according to a setting of a user. The plurality of apertures S may be at corresponding positions in odd rows, and at corresponding positions in even rows, and the odd rows and the even rows may be disposed to be offset from each other. Further, the plurality of apertures S may be disposed to form an arrangement capable of transferring the plurality of micro LEDs in a diagonal direction according to the micro LED transfer method according to the disclosure.

According to an embodiment, the mask unit 50 is formed of a material through which the laser beam may not pass, and may have heat resistance for durability against the laser beam. Further, a heat-resistant material capable of withstanding high heat of the laser beam may be applied to one surface of the mask unit 50 facing the laser light source unit 60.

According to an embodiment, the mask unit 50 may selectively open the apertures based on control of the processor 80. In case that the laser light source unit 60 scans the laser beam through the opened apertures of the mask unit 50, each micro LED on the first substrate 20 at a position corresponding to the apertures may be separated from a lower surface of the first substrate 20 by the laser beam and transferred to a upper surface of the second substrate 30. In this case, the anode electrode and the cathode electrode of each micro LED may be physically and/or electrically connected to the anode electrode pad and the cathode electrode pad of the second substrate 30, respectively, due to high heat of the laser beam.

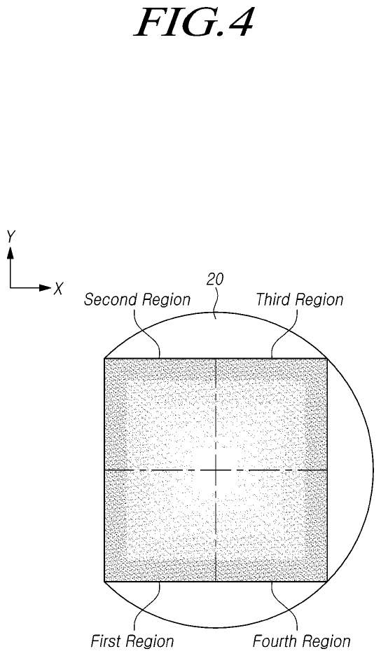

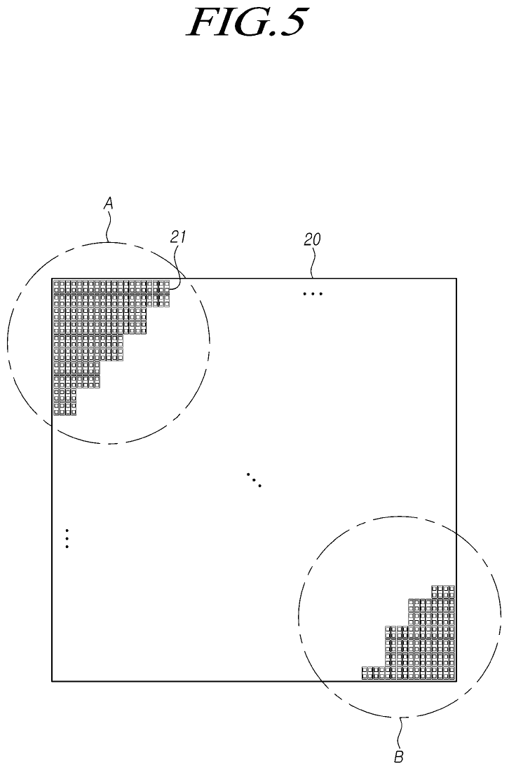

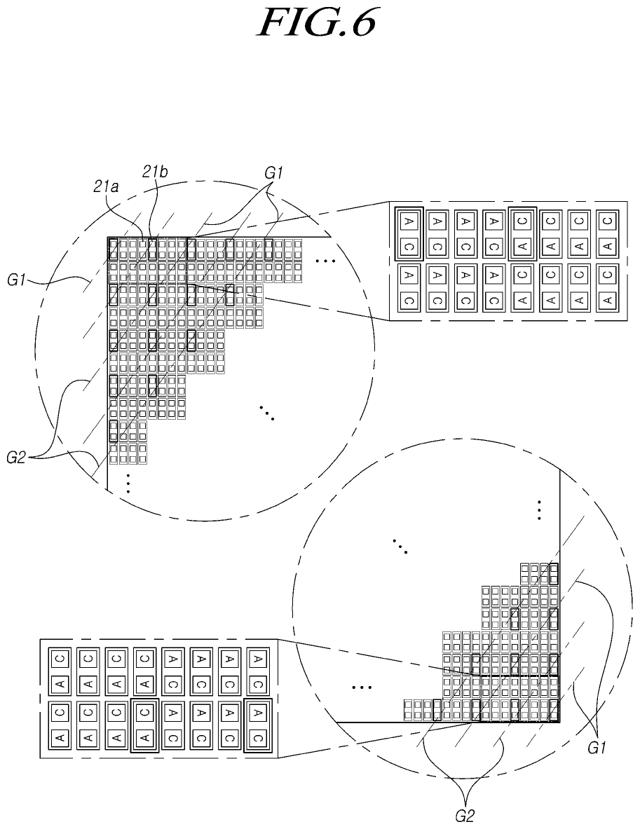

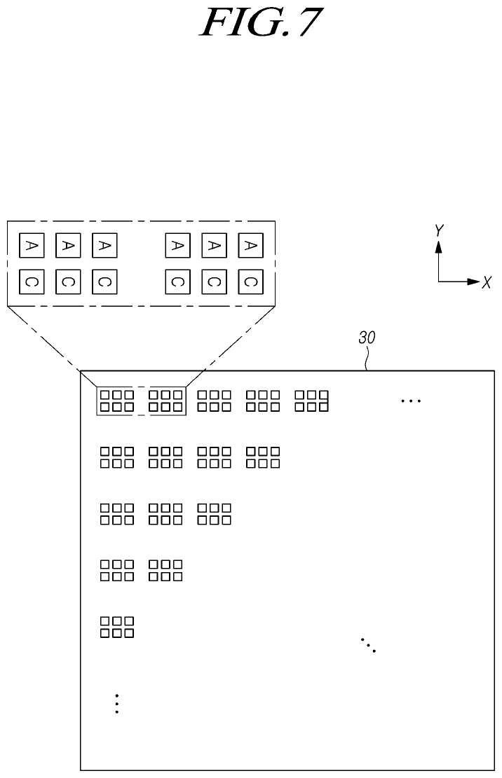

FIG. 4 illustrates the first substrate used in the first transfer device according to an embodiment, FIG. 5 illustrates an enlarged view illustrating the first region of the first substrate of FIG. 4, FIG. 6 illustrates an enlarged view illustrating a portion A and a portion B of the first region of FIG. 5, and FIG. 7 illustrates the second substrate used in the first transfer device according to an embodiment.

Referring to FIG. 4, according to an embodiment, the first substrate 20 may be a wafer and a plurality of micro LEDs 21 may be formed thereon. The plurality of micro LEDs 21 may have different performances due to process conditions and/or environments in a process of being formed on the first substrate 20. For example, as in FIG. 4, there may be a characteristic that the performance (color, luminance, etc.) of the micro LED gradually decreases from a center region of the first substrate 20 toward an outer edge.

In FIG. 4, a performance distribution of the plurality of micro LEDs formed on the first substrate 20 is represented in a gradation form. In FIG. 4, the performance distribution of the micro LED for each region (e.g., first to fourth regions) of the first substrate 20 is represented by a plurality of rectangular shapes gradually increasing in size radially from a rectangular shape indicated at a center of the first substrate 20, but this is for convenience of description only, and the performance distribution of the micro LEDs on the first substrate 20 may be represented as a gradation in a circle, an ellipse, or an irregular closed curve form, and a region with good performance of the micro LED may not necessarily correspond to a central portion of the first substrate and may be biasedly located to one side on the first substrate 20.

According to an embodiment, the first substrate 20 may partition a plurality of virtual regions on the first substrate 20 to transfer the plurality of micro LEDs to the second substrate 30 as in FIG. 4. Partitioning such virtual regions may be performed by a vision camera (not illustrated) that may be provided in the micro LED transfer device according to the disclosure and the processor 80. In this case, the virtual region information partitioned on the first substrate 20 and coordinate information of the plurality of micro LEDs disposed in each virtual region may be stored in the memory 70.

FIG. 5 illustrates the first region, which is a view illustrating the first region in a state in which the first substrate 20 is turned upside down so that the plurality of micro LEDs face downward. In FIG. 5, the plurality of micro LEDs 21 are covered by the first substrate 20 because the first substrate 20 is turned upside down, and in this case, it is common to illustrate the micro LED with a hidden line, but for convenience of description, the micro LED is illustrated with a solid line. Illustrating the first region in the turned upside down state is in consideration that the laser transfer is performed in a state in which the micro LED of the first substrate 20 is disposed to face the second substrate 30.

Referring to FIG. 5, according to an embodiment, within the first region, a micro LED with the highest performance may be located at an upper left portion, and a micro LED with the lowest performance may be located gradually toward a lower right portion from the upper left portion in a radial direction.

According to an embodiment, as in FIG. 6, in the first region, an anode electrode and a cathode electrode of some micro LEDs 21a among the plurality of micro LEDs and an anode electrode and a cathode electrode of remaining micro LEDs 21b may be formed to be disposed opposite to each other. As such, in case that the electrodes of the micro LEDs 21a, 21b are disposed at 0 degree (°) and 180 degrees (°), respectively, the second substrate 30 may be set such that the anode electrode pad and the cathode electrode pad are all in the same direction (e.g., 0 degree (°)).

In FIG. 7, the micro LED transferred to the second substrate 30 may form one pixel by three micro LEDs of red (R), green (G), and blue (B). Accordingly, the anode electrode pad and the cathode electrode pad disposed on the second substrate 30 may be disposed adjacent to each other in units of three pairs, and other pixels disposed around a single pixel may be disposed at a regular interval from the single pixel.

According to an embodiment, the laser light source unit 60 may lift off the plurality of micro LEDs 21 by irradiating a laser beam toward a rear surface of the first substrate 20 on which the plurality of micro LEDs 21 are not formed. For example, heat from the laser beam output from the laser light source unit 60 may be transferred to the adhesive layer 22 disposed between the micro LED 21 and the first substrate 20. As the adhesive force of the adhesive layer 22 is decreased by the heat, the micro LED 21 may be separated from the first substrate 20 and transferred to a transfer region on the second substrate 30.

According to an embodiment, the micro LED 21 transferred to the second substrate 30 may be physically and/or electrically connected to the anode electrode pad and the cathode electrode pad of the second substrate 30 by the anode electrode and the cathode electrode, respectively. In this case, the anode electrode pad and the cathode electrode pad of the second substrate 30 may be connected to the anode electrode and the cathode electrode of the micro LED 21 while being deformed from a solid state to a molten state by the radiated laser beam.

According to an embodiment, the micro LED transfer system of the disclosure may include at least one of a first transfer device 1 transferring a micro LED 21 to a second substrate 30, and a second transfer device 2 transferring the micro LED 21 to the second substrate 30. At least one of the first transfer device 1 or the second transfer device 2 may transfer the micro LED 21 to the second substrate 30 having an irregular shape. For example, the second substrate 30 to which the micro LED 21 of the disclosure is transferred may be a substrate having an irregular shape.

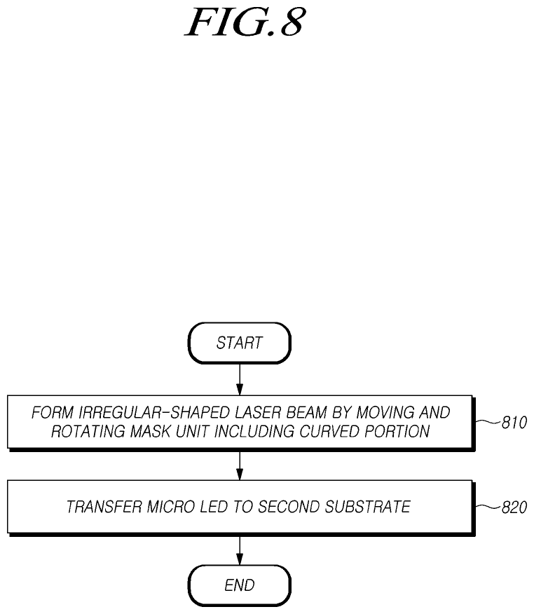

Hereinafter, a transfer manner of the micro LED to a target substrate having an irregular shape of the micro LED transfer system according to embodiments of the disclosure is described with reference to FIGS. 8 to 15.

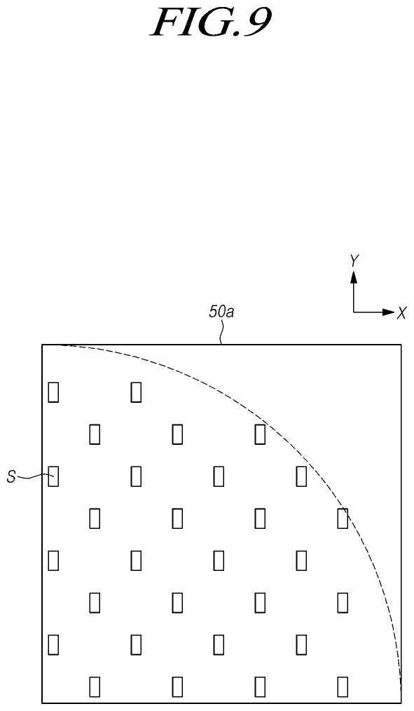

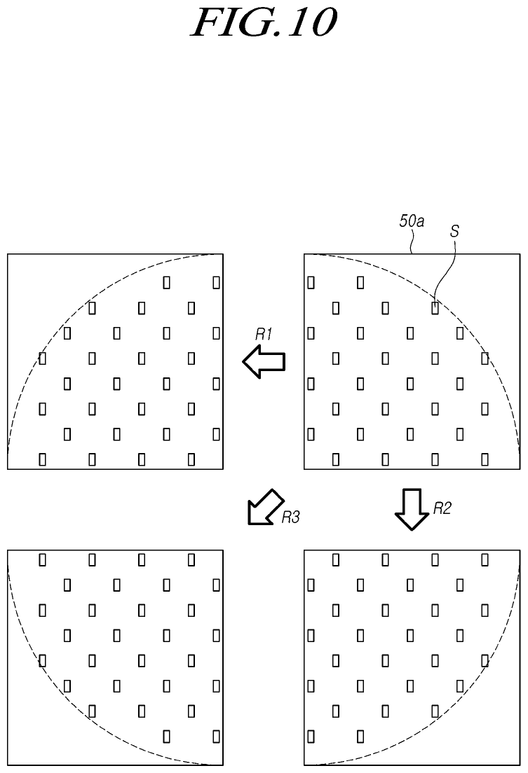

FIG. 8 illustrates a micro LED transfer operation sequence of the first transfer device 1 according to an embodiment, FIG. 9 illustrates the mask unit 50 including a curved portion according to an embodiment, and FIG. 10 illustrates the mask unit 50 moving and rotating under the control of a processor according to an embodiment.

According to an embodiment, the first transfer device 1 may include a first laser light source unit 60 irradiating a laser beam onto a first substrate 20 on which the micro LED 21 is disposed, a mask unit 50 disposed between the first substrate 20 and the first laser light source unit 60 and selectively opening and closing at least one aperture, and a first processor controlling the mask unit 50 to open and close the aperture corresponding to the micro LED 21 transferred to the second substrate 30.

Referring to FIG. 8, according to an embodiment, the first transfer device 1 may form an irregular-shaped laser beam (operation 810) by moving and rotating the mask unit 50 including a curved portion, and transfer the micro LED 21 to the second substrate 30 (operation 820).

According to an embodiment, in operation 810, the first transfer device 1 may form an irregular-shaped laser beam by moving and rotating the mask unit 50 including a curved portion. As illustrated in FIG. 9, a mask unit 50a may include a curved portion having a predetermined curvature. For example, the mask unit 50a may have a quadrant shape including the curved portion. However, the shape of the mask unit 50 of the disclosure is not limited thereto, and the shape of the mask unit 50 may include various shapes including a curved portion such as a semicircle shape and an oval shape.

According to an embodiment, the first transfer device 1 may move and rotate the mask unit 50 by controlling the transfer unit 10. For example, the processor 80 may control the transfer unit 10 to move the mask unit 50 to a position on an arbitrary XY plane above the first substrate 20. For example, the processor 80 may control the transfer unit 10 to rotate the mask unit 50 clockwise or counterclockwise above the first substrate 20.

According to an embodiment, the first transfer device 1 may form an irregular-shaped laser beam by passing the laser beam through the plurality of apertures S of the mask unit 50 that has been moved and rotated. As illustrated in FIG. 10, the first transfer device 1 may rotate (R1) the mask unit 50a by 90 degrees (°) clockwise, rotate (R2) the mask unit 50a by 90 degrees (°) counterclockwise, or rotate (R3) the mask unit 50a by 180 degrees (°) clockwise or counterclockwise. For example, the first transfer device 1 may form a circle-shaped laser beam by moving and rotating the mask unit 50a having a quadrant shape.

According to an embodiment, in operation 820, the first transfer device 1 may transfer the micro LED 21 to the second substrate 30. For example, in case that the first transfer device 1 scans an irregular-shaped laser beam onto the first substrate 20 by moving and rotating the mask unit 50, each micro LED 21 on the first substrate 20 at a position corresponding to the apertures of the mask unit 50 may be separated from a lower surface of the first substrate 20 by the laser beam and transferred to an upper surface of the second substrate 30. In this case, the anode electrode and the cathode electrode of each micro LED 21 may be physically and/or electrically connected to the anode electrode pad and the cathode electrode pad of the second substrate 30, respectively, due to high heat of the laser beam.

According to an embodiment, the micro LED transfer system of the disclosure and the micro LED transfer method using the same may transfer the micro LED 21 onto a target substrate having an irregular shape by moving and rotating the mask unit 50 including a curved portion. Accordingly, the micro LED transfer system of the disclosure and the micro LED transfer method using the same may efficiently transfer the micro LED 21 to a target substrate having an irregular shape applicable to a display device having various shapes.

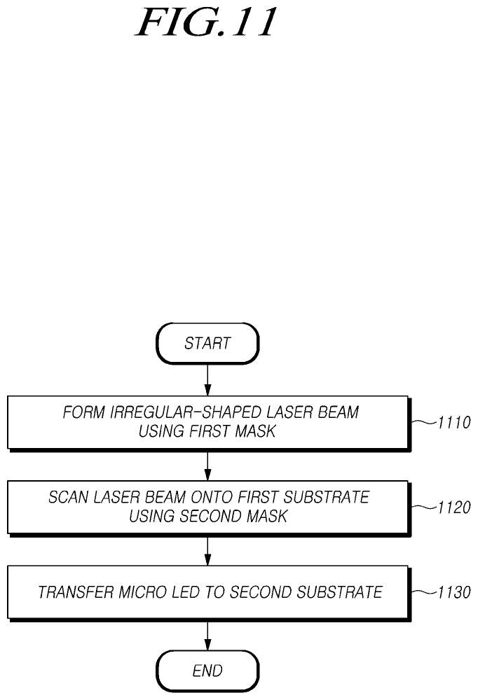

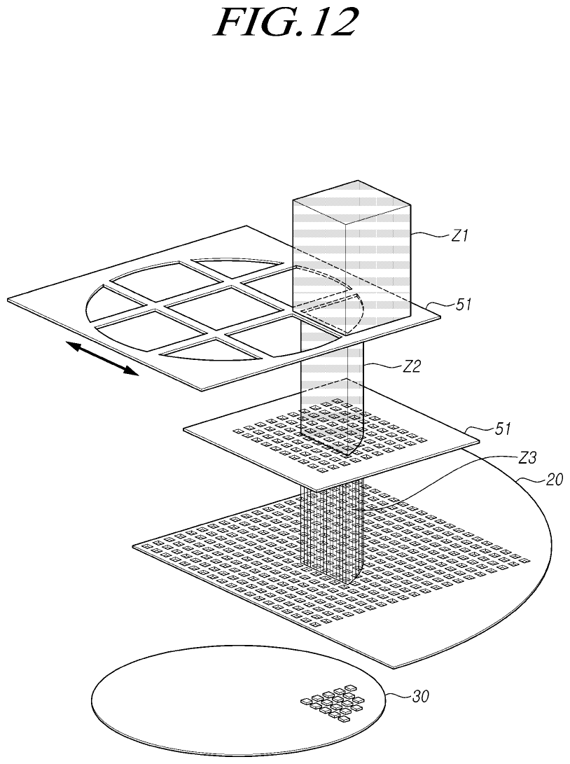

FIG. 11 illustrates a micro LED transfer operation sequence of the first transfer device 1 according to an embodiment, and FIG. 12 illustrates a laser beam sequentially passing through a first mask and a second mask.

According to an embodiment, the first transfer device 1 may include a first laser light source unit 60 irradiating a laser beam onto a first substrate 20 on which the micro LED 21 is disposed, a mask unit 50 disposed between the first substrate 20 and the first laser light source unit 60 and selectively opening and closing at least one aperture, and a first processor controlling the mask unit 50 to open and close the aperture corresponding to the micro LED 21 transferred to the second substrate 30.

Referring to FIG. 11, according to an embodiment, the first transfer device 1 may form an irregular-shaped laser beam using a first mask (operation 1110), scan a laser beam onto the first substrate 20 using a second mask (operation 1120), and transfer the micro LED 21 to the second substrate 30 (operation 1130).

According to an embodiment, in operation 1110, the first transfer device 1 may form an irregular-shaped laser beam using the first mask. The mask unit 50 may include a first mask shaping the laser beam and a second mask scanning the laser beam onto the first substrate 20.

Referring to FIG. 12, the first mask may be disposed above the second mask. For example, the first mask may be a blind mask. The first mask may include a shaping aperture for shaping a laser beam Z1 incident from the laser light source unit 60 into a predetermined shape. For example, the first mask may include a shaping aperture having at least one shape among a rectangle, a triangle, a circle, a semicircle, or a quadrant.

According to an embodiment, the first transfer device 1 may form an irregular-shaped laser beam Z2 by moving and rotating the first mask. For example, the first mask may be moved and rotated by the transfer unit 10, and shape the laser beam Z1 into various shapes according to combinations of shaping apertures having different shapes. For example, the first transfer device 1 may shape the laser beam Z1 into a laser beam Z2 having various shapes including a circle, a semicircle, a quadrant, and/or a curved portion using the first mask.

According to an embodiment, in operation 1120, the first transfer device 1 may scan a laser beam onto the first substrate 20 using the second mask. For example, the first transfer device 1 may scan the shaped laser beam Z3 onto the micro LED 21 on the first substrate 20 at a position corresponding to the apertures by passing the laser beam Z2 shaped while passing through the first mask through the opened apertures of the second mask.

According to an embodiment, in operation 1130, the first transfer device 1 may transfer the micro LED 21 to the second substrate 30. For example, in case that the first transfer device 1 scans the laser beam shaped through the first mask and the second mask onto the first substrate 20, the micro LED 21 on the first substrate 20 corresponding to the shaped laser beam may be separated from a lower surface of the first substrate 20 by the laser beam and transferred to an upper surface of the second substrate 30. In this case, the anode electrode and the cathode electrode of each micro LED 21 may be physically and/or electrically connected to the anode electrode pad and the cathode electrode pad of the second substrate 30, respectively, due to high heat of the laser beam.

According to an embodiment, the micro LED transfer system of the disclosure and the micro LED transfer method using the same may transfer the micro LED 21 onto a target substrate having an irregular shape by shaping the laser beam with the first mask and scanning the laser beam onto the wafer with the second mask. Accordingly, the micro LED transfer system of the disclosure and the micro LED transfer method using the same may efficiently transfer the micro LED 21 to a target substrate having an irregular shape applicable to a display device having various shapes.

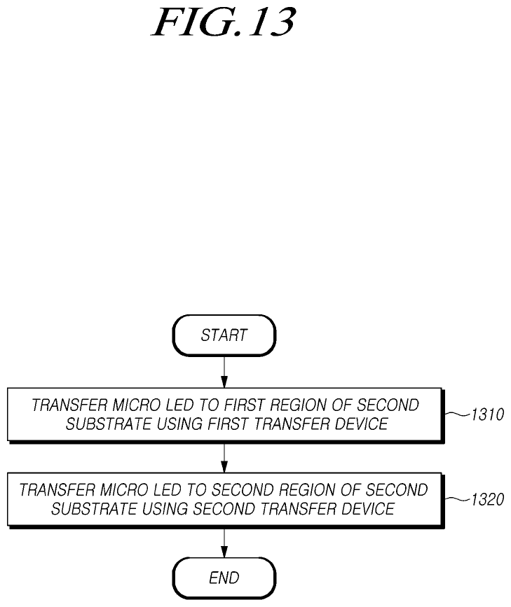

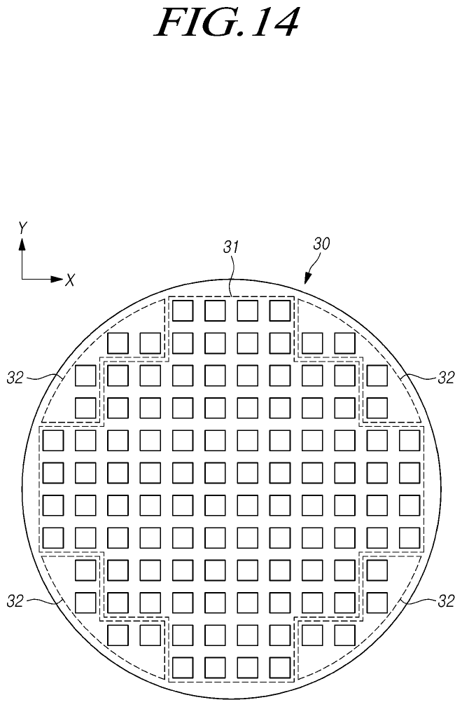

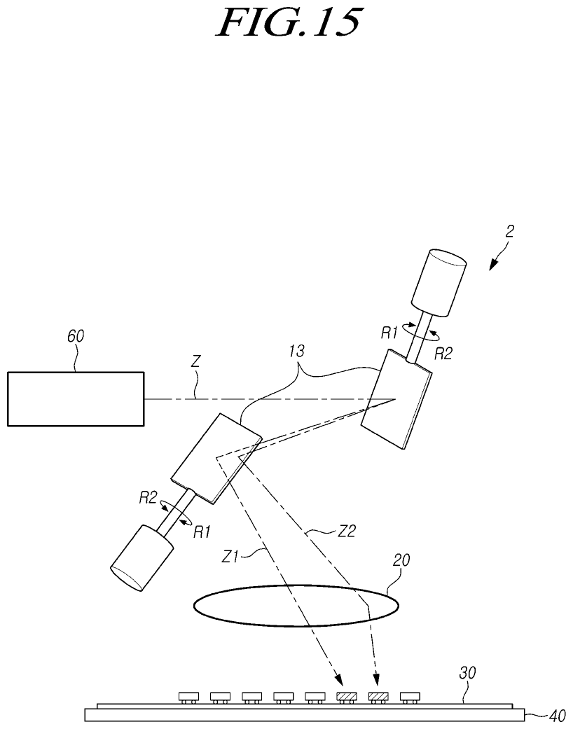

FIG. 13 illustrates a micro LED transfer operation sequence of the first transfer device 1 and the second transfer device 2 according to an embodiment, FIG. 14 illustrates a first region and a second region of the second substrate 30, and FIG. 15 illustrates the second transfer device 2 of the micro LED transfer system according to an embodiment.

Referring to FIG. 13, according to an embodiment, the micro LED transfer system may transfer the micro LED 21 to the first region of the second substrate 30 using the first transfer device 1 (operation 1310), and transfer the micro LED 21 to the second region of the second substrate 30 using the second transfer device 2 (operation 1320).

According to an embodiment, the first transfer device 1 may transfer the micro LED 21 to the second substrate 30 in a multi transfer manner. Further, the second transfer device 2 may transfer the micro LED 21 to the second substrate 30 in a one-by-one transfer manner.

Referring to FIG. 14, according to an embodiment, the second substrate 30 may be a substrate having an irregular shape (e.g., a circular shape). A transfer region of the second substrate 30 may be divided into a first region 31 and a second region 32. For example, the second substrate 30 may include a first region 31 including a non-curved region, and a second region 32 including a curved region. The first region 31 is a transfer region formed on an inner side of the second substrate 30 and may be a region having a regular shape (e.g., a rectangular shape). The second region 32 is a transfer region formed on an edge of the second substrate 30 and may be a region having an irregular shape (e.g., a shape including a curved portion). For example, the second region 32 may be a region surrounding the first region 31.

According to an embodiment, in operation 1310, the micro LED transfer system may transfer the micro LED 21 to the first region of the second substrate 30 using the first transfer device 1.

According to an embodiment, the first transfer device 1 may include a first laser light source unit 60 irradiating a laser beam onto a first substrate 20 on which the micro LED 21 is disposed, a mask unit 50 disposed between the first substrate 20 and the first laser light source unit 60 and selectively opening and closing at least one aperture, and a first processor controlling the mask unit 50 to open and close the aperture corresponding to the micro LED 21 transferred to the second substrate 30.

According to an embodiment, the first transfer device 1 may rapidly transfer the micro LED 21 to the first region 31 having a regular shape (e.g., a rectangular shape) in a multi transfer manner. For example, in case that the first laser light source unit 60 scans the laser beam onto the first substrate 20 through the mask unit 50, each micro LED 21 on the first substrate 20 at a position corresponding to the apertures of the mask unit 50 may be separated from a lower surface of the first substrate 20 by the laser beam and transferred to the first region 31 of the second substrate 30.

According to an embodiment, in operation 1320, the micro LED transfer system may transfer the micro LED 21 to the second region 32 of the second substrate 30 using the second transfer device 2. For example, the second transfer device 2 may sequentially transfer the micro LED 21 to the second region 32 of the second substrate 30 after the first transfer device 1 transfers the micro LED 21 to the first region 31 of the second substrate 30.

According to an embodiment, the second transfer device 2 may include a second laser light source unit 60 outputting a laser beam, a path changing unit 13 changing a path of the laser beam, and a second processor controlling the path changing unit 13 to change the path of the laser beam toward the micro LED 21 transferred to the second substrate 30.

According to an embodiment, the second transfer device 2 may precisely transfer the micro LED 21 to the second region 32 having an irregular shape (e.g., a shape including a curved portion) in a one-by-one transfer manner. For example, as illustrated in FIG. 15, the second laser light source unit 60 may output a laser beam to the path changing unit 13. The path changing unit 13 may rapidly change a path of a laser beam Z emitted from the second laser light source unit 60, and change a point light source laser beam to be close to a surface light source or a line light source.

According to an embodiment, the path changing unit 13 may change the laser beam Z output from the second laser light source unit 60 in units of ms, μs (micro sec), and ns (nano sec), and radiate the laser beam Z to a predetermined position of the first substrate 20 on which the micro LED 21 is disposed. Here, since the laser beam Z changed by the path changing unit 13 is radiated onto the first substrate 20 in units of ms, μs (micro sec), and ns (nano sec), the micro LED 21 may be transferred to the second region 32 of the second substrate 30 at the same time as being separated from the first substrate 20.

For example, the path changing unit 13 may include a Galvano mirror. The Galvano mirror may be a device capable of rapidly changing a path of a light source by rapidly rotating a mirror reflecting the light source. As illustrated in FIG. 15, the second processor may change the path of the laser beam Z so that the micro LED 21 is transferred to the second region 32 by controlling the path changing unit 13 in preset rotation directions R1, R2 based on position information of the second region 32 to be transferred. For example, the laser beam Z may be sequentially reflected by the Galvano mirror and scanned onto the first substrate 20 through a first laser path Z1 and a second laser path Z2, so that the micro LED 21 may be accurately transferred to the second region 32 of the second substrate 30.

According to an embodiment, the micro LED transfer system of the disclosure and the micro LED transfer method using the same may transfer the micro LED 21 onto a target substrate having an irregular shape by transferring the micro LED 21 to a non-curved portion of the target substrate with the first transfer device 1 in a multi transfer manner and transferring the micro LED 21 to a curved portion of the target substrate with the second transfer device 2 in a one-by-one transfer manner. Accordingly, the micro LED transfer system of the disclosure and the micro LED transfer method using the same may efficiently transfer the micro LED 21 to a target substrate having an irregular shape applicable to a display device having various shapes.

The various embodiments of this document and the terms used herein are not intended to limit the technical features described in this document to specific embodiments, and should be understood to include various modifications, equivalents, or alternatives of the corresponding embodiments. As used herein, the singular forms “a,” “an,” and “the” are intended to include the plural forms as well, unless the context clearly indicates otherwise. As used herein, the term ‘and/or’ should be understood as encompassing any and all possible combinations by one or more of the enumerated items. As used herein, the terms “include,” “have,” and “comprise” are used merely to designate the presence of the feature, component, part, or a combination thereof described herein, but use of the term does not exclude the likelihood of presence or adding one or more other features, components, parts, or combinations thereof. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

As used herein, the term “part” or “module” may include a unit implemented in hardware, software, or firmware, and may interchangeably be used with other terms, for example, “logic,” “logic block,” “part,” or “circuitry”. A part or module may be a single integral component, or a minimum unit or part thereof, adapted to perform one or more functions. For example, according to an embodiment, ‘part’ or ‘module’ may be implemented in a form of an application-specific integrated circuit (ASIC).

As used in various embodiments of the disclosure, the term “if” may be interpreted as “when,” “upon,” “in response to determining,” or “in response to detecting,” depending on the context. Similarly, “if A is determined” or “if A is detected” may be interpreted as “upon determining A” or “in response to determining A”, or “upon detecting A” or “in response to detecting A”, depending on the context.

The program executed by the transfer device described herein may be implemented as a hardware component, a software component, and/or a combination thereof. The program may be executed by any system capable of executing computer readable instructions.

The software may include computer programs, codes, instructions, or combinations of one or more thereof and may configure the processing device as it is operated as desired or may instruct the processing device independently or collectively. The software may be implemented as a computer program including instructions stored in computer-readable storage media. The computer-readable storage media may include, e.g., magnetic storage media (e.g., read-only memory (ROM), random-access memory (RAM), floppy disk, hard disk, etc.) and an optically readable media (e.g., CD-ROM or digital versatile disc (DVD). Further, the computer-readable storage media may be distributed to computer systems connected via a network, and computer-readable codes may be stored and executed in a distributed manner. The computer program may be distributed (e.g., downloaded or uploaded) via an application store (e.g., Play Store™), directly between two UEs (e.g., smartphones), or online. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

1. A micro light emitting diode (LED) transfer system, comprising:
at least one of a first transfer device to transfer the micro LED to a second substrate, and a second transfer device to transfer the micro LED to the second substrate,
wherein the first transfer device includes:
a first laser light source unit to irradiate a laser beam onto a first substrate on which the micro LED is disposed;
a mask unit, to be disposed between the first substrate and the first laser light source unit, selectively open and close at least one aperture; and
a processor, including a processing circuit, to control the mask unit to open and close the at least one aperture corresponding to the micro LED transferred to the second substrate, and
wherein at least one of the first transfer device or the second transfer device is configured to transfer the micro LED to the second substrate having an irregular shape.

2. The micro LED transfer system of claim 1, wherein the mask unit includes a curved portion having a predetermined curvature, and
wherein the processor is configured to form an irregular-shaped laser beam by moving and rotating the mask unit.

3. The micro LED transfer system of claim 2, wherein the mask unit has a quadrant shape including the curved portion, and
wherein the processor is configured to form a circle-shaped laser beam by moving and rotating the mask unit.

4. The micro LED transfer system of claim 1, wherein the mask unit includes:
a first mask shaping the laser beam; and
a second mask scanning the laser beam onto the first substrate.

5. The micro LED transfer system of claim 4, wherein the first mask includes a shaping aperture having at least one shape among a rectangle, a triangle, a circle, a semicircle, or a quadrant.

6. The micro LED transfer system of claim 4, wherein the processor is configured to form an irregular-shaped laser beam by moving and rotating the first mask.

7. The micro LED transfer system of claim 1, wherein the first transfer device is configured to transfer the micro LED to the second substrate in a multi transfer manner, and
wherein the second transfer device is configured to transfer the micro LED to the second substrate in a one-by-one transfer manner.

8. The micro LED transfer system of claim 1, wherein the processor is a first processor and the second transfer device includes:
a second laser light source unit outputting a laser beam;
a path changing unit changing a path of the laser beam; and
a second processor controlling the path changing unit to change the path of the laser beam toward the micro LED transferred to the second substrate.

9. The micro LED transfer system of claim 8, wherein the first transfer device is configured to transfer the micro LED to a first region of the second substrate, and
wherein the second transfer device is configured to transfer the micro LED to a second region of the second substrate.

10. The micro LED transfer system of claim 9, wherein the first region includes a non-curved region of the second substrate, and
wherein the second region includes a curved region of the second substrate.

11. A micro LED transfer method, comprising:
transferring a micro LED to a second substrate using a first transfer device; and
transferring the micro LED to the second substrate using a second transfer device, wherein transferring the micro LED to the second substrate using the first transfer device includes:
irradiating a laser beam onto a first substrate on which the micro LED is disposed using a first laser light source unit;
selectively opening and closing at least one aperture using a mask unit disposed between the first substrate and the first laser light source unit; and
controlling the mask unit to open and close the at least one aperture corresponding to the micro LED transferred to the second substrate using a processor, and
wherein at least one of the first transfer device and the second transfer device is configured to transfer the micro LED to the second substrate having an irregular shape.

12. The micro LED transfer method of claim 11, wherein the mask unit includes a curved portion having a predetermined curvature, and
wherein controlling the mask unit using the processor includes forming an irregular-shaped laser beam by moving and rotating the mask unit.

13. The micro LED transfer method of claim 12, wherein the mask unit has a quadrant shape including the curved portion, and
wherein controlling the mask unit using the processor includes forming a circle-shaped laser beam by moving and rotating the mask unit.

14. The micro LED transfer method of claim 11, wherein selectively opening and closing at least one aperture using the mask unit includes:
shaping the laser beam using a first mask; and
scanning the laser beam onto the first substrate using a second mask.

15. The micro LED transfer method of claim 14, wherein the first mask includes a shaping aperture having at least one shape among a rectangle, a triangle, a circle, a semicircle, and a quadrant.

16. The micro LED transfer method of claim 14, wherein controlling the mask unit using the processor includes forming an irregular-shaped laser beam by moving and rotating the first mask.

17. The micro LED transfer method of claim 11, wherein the first transfer device may transfer the micro LED to the second substrate in a multi transfer manner and the second transfer device may transfer the micro LED to the second substrate in a one-by-one transfer manner.

18. The micro LED transfer method of claim 11, wherein transferring the micro LED to the second substrate using the second transfer device may include outputting a laser beam using a second laser light source unit, changing a path of the laser beam using a path changing unit, and controlling the path changing unit to change the path of the laser beam toward the micro LED transferred to the second substrate using a second processor.

19. The micro LED transfer method of claim 18, wherein transferring the micro LED to the second substrate using the first transfer device may transfer the micro LED to a first region of the second substrate, and wherein transferring the micro LED to the second substrate using the second transfer device may transfer the micro LED to a second region of the second substrate.

20. The micro LED transfer method of claim 19, wherein the first region may include a non-curved region of the second substrate, and wherein the second region may include a curved region of the second substrate.
